(19) United States
(12) Patent Application Publication
(10) Pub. No.: US 2025/0331376 A1
(43) Pub. Date: Oct. 23, 2025

(54) DISPLAY DEVICE AND ELECTRONIC DEVICE FOR PROVIDING IMAGE

(71) Applicant: Samsung Display Co., Ltd., Yongin-Si (KR)

(72) Inventors: Hyung Jin SONG, Yongin-si (KR); Soo Jo OCK, Yongin-si (KR); Kwang Sae LEE, Yongin-si (KR); Chang Won JEONG, Yongin-si (KR); Chae Han HYUN, Yongin-si (KR)

(21) Appl. No.: 18/953,153

(22) Filed: Nov. 20, 2024

(30) Foreign Application Priority Data
Apr. 22, 2024 (KR) 10-2024-0053379

(51) Int. Cl. H10K 59/131

(52) U.S. Cl. CPC H10K 59/131

(57) ABSTRACT

A display device according to an embodiment includes a substrate including a display area and a non-display area, pixels disposed in the display area on the substrate, and data lines including first data lines and second data lines disposed in the display area and the non-display area on the substrate. The non-display area includes a first wiring area in which the first data lines are disposed and a second wiring area in which the second data lines are disposed, and at least one data line disposed adjacent to a boundary between the first wiring area and the second wiring area includes protruding patterns which protrude in a first direction intersecting a longitudinal direction of the data lines.

### CROSS-REFERENCE TO RELATED APPLICATION

This application claims priority to Korean Patent Application No. 10-2024-0053379 filed on Apr. 22, 2024, in the Korean Intellectual Property Office, and all the benefits accruing therefrom under 35 U.S.C. 119, the contents of which in its entirety are incorporated herein by reference.

### BACKGROUND

### 1. Technical Field

The present disclosure relates to a display device and an electronic device for providing an image.

### 2. Description of the Related Art

With the advance of information-oriented society, increased demands are placed on display devices for displaying images in various ways. Along with this trend, various types of display devices including a light-emitting display device are being developed.

A display device includes pixels connected to scan lines and data lines. Each of the pixels emit light with a luminance corresponding to the data signals in response to scan signals and data signals applied to the scan lines and the data lines, respectively.

### SUMMARY

Aspects of the present disclosure provide a display device and an electronic device for providing an image capable of reducing capacitance variation of data lines.

However, aspects of the present disclosure are not restricted to embodiments set forth herein. The above and other aspects of the present disclosure will become more apparent to one of ordinary skill in the art to which the present disclosure pertains by referencing the detailed description of the present disclosure given below.

According to an aspect of the present disclosure, there is provided a display device including, a substrate including a display area and a non-display area, pixels disposed in the display area on the substrate, and data lines including first data lines and second data lines disposed in the display area and the non-display area on the substrate. The non-display area may include a first wiring area in which the first data lines are disposed and a second wiring area in which the second data lines are disposed. At least one data line disposed adjacent to a boundary between the first wiring area and the second wiring area may include protruding patterns which protrude in a first direction intersecting a longitudinal direction of the data lines.

In an embodiment, the first direction may be a width direction of the data lines, and a width of the at least one data line may be partially expanded at portions where the protruding patterns are disposed.

In an embodiment, a plurality of data lines disposed adjacent to the boundary may include the protruding patterns, and a gap between adjacent data lines of the plurality of data lines may be partially reduced at the portions where the protruding patterns are disposed.

In an embodiment, the display device may further include a driving circuit disposed in the non-display area on the substrate, and the data lines may be connected between the driving circuit and the pixels.

In an embodiment, the non-display area may include a first non-display area, a bending area, and a second non-display area sequentially disposed along a second direction intersecting the first direction between the display area and the driving circuit.

In an embodiment, the first wiring area and the second wiring area may be sequentially disposed along the first direction in the first non-display area, the bending area, and the second non-display area.

In an embodiment, the display device may further include an isolation area which is disposed between the first wiring area and the second wiring area in the non-display area. The data lines may not be disposed in the isolation area.

In an embodiment, the first data lines may be consecutively disposed along the first direction in the first wiring area, the second data lines may be consecutively disposed along the first direction in the second wiring area, and the isolation area is disposed between the first data lines and the second data lines in the non-display area.

In an embodiment, the display device may further include a power line disposed in the display area and the non-display area on the substrate, and the power line may be disposed in the isolation area in the non-display area.

In an embodiment, the data lines may include straight portions extending in the second direction and diagonal portions extending in a diagonal direction intersecting the first and second directions and arranged more densely than the straight portions.

In an embodiment, a plurality of data lines disposed adjacent to the boundary may include the protruding patterns, and the protruding patterns may protrude in the first direction from the respective straight portions of the plurality of data lines.

In an embodiment, the first wiring area and the second wiring area may be sequentially disposed along the first direction in the second non-display area, and data lines disposed close to the boundary may include the protruding patterns.

In an embodiment, at least two data lines disposed adjacent to each other may include different numbers of protruding patterns.

In an embodiment, a data line disposed closer to the boundary may include a greater number of protruding patterns than that disposed far from the boundary.

In an embodiment, first data lines disposed close to the boundary may include the protruding patterns, and second data lines disposed close to the boundary may not include the protruding patterns.

In an embodiment, second data lines disposed close to the boundary between the first wiring area and the second wiring area may include the protruding patterns, and first data lines disposed close to the boundary between the first wiring area and the second wiring area may not include the protruding patterns.

In an embodiment, first data lines and second data lines disposed close to the boundary between the first wiring area and the second wiring area may include the protruding patterns.

In an embodiment, protruding patterns disposed in the first wiring area and the second wiring area may be disposed symmetrically with respect to the boundary between the first wiring area and the second wiring area.

In an embodiment, protruding patterns disposed adjacent to each other may have an interlocked shape.

In an embodiment, the data lines may be alternately disposed in a first conductive layer on the substrate and a second conductive layer on an insulating layer covering the first conductive layer in the non-display area.

According to an aspect of the present disclosure, there is provided an electronic for providing an image, including a display device including, a substrate including a display area and a non-display area, pixels disposed in the display area on the substrate, and data lines including first data lines and second data lines disposed in the display area and the non-display area on the substrate. The non-display area may include a first wiring area in which the first data lines are disposed and a second wiring area in which the second data lines are disposed. At least one data line disposed adjacent to a boundary between the first wiring area and the second wiring area may include protruding patterns which protrude in a first direction intersecting a longitudinal direction of the data lines.

In accordance with the display device according to embodiments, the capacitance variation of the data lines may be reduced or minimized. Accordingly, the data signals may be stably transmitted to the pixels, and the image quality of the display device may be improved.

However, effects according to the embodiments of the present disclosure are not limited to those exemplified above and various other effects are incorporated herein.

### BRIEF DESCRIPTION OF THE DRAWINGS

The above and other aspects and features of the present disclosure will become more apparent by describing in detail embodiments thereof with reference to the attached drawings, in which:

FIG. 1 is a plan view illustrating a display device according to one embodiment;

FIG. 2 is an equivalent circuit diagram illustrating a pixel according to one embodiment;

FIG. 3 is a cross-sectional view illustrating a display device according to one embodiment;

FIG. 4 is a plan view illustrating area A1 of FIG. 1 in detail;

FIGS. 5, 6, 7, 8 and 9 are plan views showing area A2 in FIG. 4 in detail;

FIG. 10 is a plan view showing area A3 of FIG. 5 in detail; and

FIG. 11 is a cross-sectional view showing a display device according to one embodiment.

### DETAILED DESCRIPTION OF THE EMBODIMENTS

The present inventive concept will now be described more fully hereinafter with reference to the accompanying drawings, in which preferred embodiments of the inventive concept are shown. This inventive concept may, however, be embodied in different forms and should not be construed as limited to the embodiments set forth herein. Rather, these embodiments are provided so that this disclosure will be thorough and complete, and will fully convey the scope of the inventive concept to those skilled in the art.

It will also be understood that when an element or a layer is referred to as being “on” another element or layer, it can be directly on the other element or layer, or intervening layers may also be present. The same reference numbers indicate the same components throughout the specification.

It will be understood that, although the terms “first,” “second,” etc. may be used herein to describe various elements, these elements should not be limited by these terms. These terms are only used to distinguish one element from another element. For instance, a first element discussed below could be termed a second element without departing from the teachings of the present inventive concept. Similarly, the second element could also be termed the first element.

Features of each of various embodiments of the present disclosure may be partially or entirely combined with each other and may technically variously interwork with each other, and respective embodiments may be implemented independently of each other or may be implemented together in association with each other.

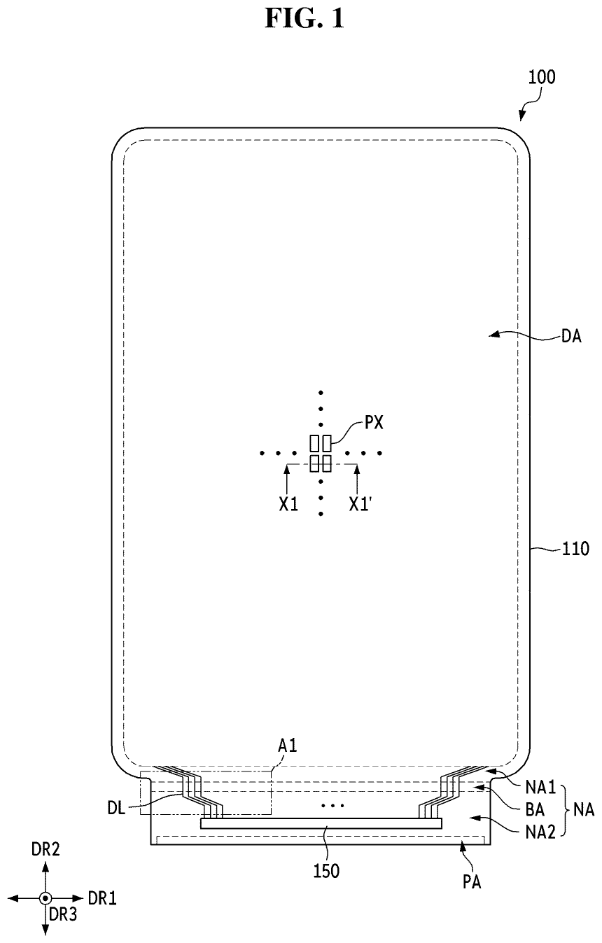

FIG. 1 is a plan view illustrating a display device according to one embodiment.

Referring to FIG. 1, a display device 100 may include a substrate 110 and pixels PX disposed on the substrate 110. The display device 100 may further include a driving circuit 150 electrically connected to the pixels PX. In one embodiment, the driving circuit 150 may be disposed on the substrate 110.

The substrate 110 may be a base layer for manufacturing or providing the display device 100. The substrate 110 and the display device 100 including the same may include a display area DA and a non-display area NA.

The display area DA may be an area where an image is displayed. The pixels PX and wires (or some of the wires) connected to the pixels PX may be disposed in the display area DA. In describing embodiments, the term “connect” may include electrical connection and/or physical connection.

In one embodiment, the display area DA may have a planar shape that includes a short side in a first direction DR1 and a long side in a second direction DR2 and has a substantially rectangular shape. A corner portion at which the long side and the short side of the display area DA meet may be rounded or right-angled. The shape of the display area DA may be variously changed according to embodiments. For example, the display area DA may be formed in a polygonal shape other than a quadrilateral shape, a circular shape, an elliptical shape, or the like. In FIG. 1, the first direction DR1 and the second direction DR2 may be horizontal and vertical directions of the display device 100 (or the substrate 110), respectively. A third direction DR3 may be a direction crossing the main surface of the display device 100 defined by the first direction DR1 and the second direction DR2. For example, the third direction DR3 may be a thickness direction of the display device 100 or the substrate 110.

In one embodiment, the display device 100 defined by the first direction DR1 and the second direction DR2 may be substantially flat and may have a predetermined thickness (or height) in the third direction DR3. In another embodiment, the display device 100 may include a curved portion in at least a part. The display device 100 may be formed rigidly so as not to be substantially deformed, or may be formed flexibly to be curved, warped, bent, folded, or rolled in at least a part.

The non-display area NA, which is an area except the display area DA, may be disposed around the display area DA. For example, the non-display area NA may surround the display area DA. Wires (e.g., some of wires extending from the display area DA to the non-display area NA) connected to the pixels PX may be disposed in the non-display area NA. In one embodiment, the driving circuit 150 may be further disposed in the non-display area NA.

The driving circuit 150 may include a data driving circuit. The data driving circuit may be electrically connected to the pixels PX through data lines DL.

In one embodiment, the driving circuit 150 may be formed as an integrated circuit (IC) chip and may be disposed or mounted on the non-display area NA of the substrate 110, but the present disclosure is not limited thereto. For example, the driving circuit 150 may be disposed on a circuit board (e.g., FPCB) electrically connected to pads of a pad area PA.

Data lines DL may be disposed or connected between the driving circuit 150 and the pixels PX. For example, the data lines DL may be disposed in the display area DA and the non-display area NA, a part (e.g., a spider line portion of each of the data lines DL) of the data lines DL located in the non-display area NA may be connected to the driving circuit 150, and the other part of the data lines DL located in the display area DA may be connected to the pixels PX. The data lines DL may transmit data signals output from the driving circuit 150 to the pixels PX.

FIG. 1 shows a part of the data lines DL disposed between the display area DA and the driving circuit 150. A part of the data lines DL disposed between the display area DA and the driving circuit 150 may be distinguished from another part of the data lines DL disposed in the display area DA, and may be referred to as connection lines, spider lines, or fan-out lines.

In one embodiment, a scan driving circuit (not shown) may be further disposed in the non-display area NA. For example, the display device 100 may further include a scan driving circuit disposed on at least one side (e.g., at least one of the left side or the right side) of the display area DA and scan lines connected between the scan driving circuit and the pixels PX. In one embodiment, the scan driving circuit may be formed on the substrate 110 together with the pixels PX, but the present disclosure is not limited thereto.

The substrate 110 and the display device 100 including the same may further include the pad area PA. The pads electrically connected to the driving circuit 150 and the pixels PX may be disposed in the pad area PA. For example, power pads and signal pads for transmitting driving voltages and driving signals to the pixels PX and the driving circuit 150 may be disposed in the pad area PA.

Although the pad area PA and the non-display area NA are distinguished and illustrated in FIG. 1, embodiments are not limited thereto. For example, the pad area PA may be considered as a part of the non-display area NA.

In one embodiment, the display device 100 may further include an additional component. For example, the display device 100 may further include a timing controller and a power supply circuit.

In one embodiment, the display device 100 may be a light-emitting display device including a light-emitting element. For example, the display device 100 may be a light-emitting display device such as an organic light-emitting display including an organic light-emitting diode, a quantum dot light-emitting display including a quantum dot light-emitting layer, an inorganic light-emitting display including an inorganic semiconductor, or an ultra-small light-emitting display using an ultra-small light-emitting diode such as a micro or nano light-emitting diode (micro LED or nano LED). However, the embodiments are not limited thereto. For example, the display device 100 may be another type of display device other than a light-emitting display device.

In the following, embodiments in which the display device 100 is an organic light-emitting display device will be disclosed. However, the display device 100 according to embodiments is not limited to the organic light-emitting display device, and technical features of embodiments to be described later may be applied to other types of display devices.

In one embodiment, the display device 100 may include a bending area BA (also referred to as “bending portion”). In one embodiment, the bending area BA may be located in the non-display area NA at the lower side of the display area DA. For example, the bending area BA may be located between the display area DA and the pad area PA in the second direction DR2 and may extend in the first direction DR1.

The non-display area NA may include a first non-display area NA1 surrounding the display area DA, and a second non-display area NA2 disposed between the first non-display area NA1 and the pad area PA. In one embodiment, the non-display area NA may further include the bending area BA disposed between the first non-display area NA1 and the second non-display area NA2. The first non-display area NA1 may be immediately adjacent to the display area DA. The second non-display area NA2 may be spaced apart from the first non-display area NA1 with the bending area BA disposed therebetween. For example, between the display area DA and the driving circuit 150, the first non-display area NA1, the bending area BA, and the second non-display area NA2 may be disposed sequentially along the second direction DR2.

In one embodiment, the driving circuit 150 may be disposed in the second non-display area NA2. For example, the second non-display area NA2 may include a driving circuit arrangement area where the driving circuit 150 is disposed.

The display device 100 may be bent in the bending area BA. For example, when the display device 100 is a front emitting display device, the display device 100 may be bent such that the second non-display area NA2 and the pad area PA are located on the back surface of the display device 100. Accordingly, the width of a bezel area may be reduced or minimized. Whether the display device 100 is bent and/or the position of the bending area BA may be modified in various ways according to embodiments. For example, in another embodiment, the bending area BA may be located across the display area DA and the non-display area NA, and the display area DA may also be bent. In still another embodiment, the display device 100 may not include the bending area BA and may maintain a fully unfolded state.

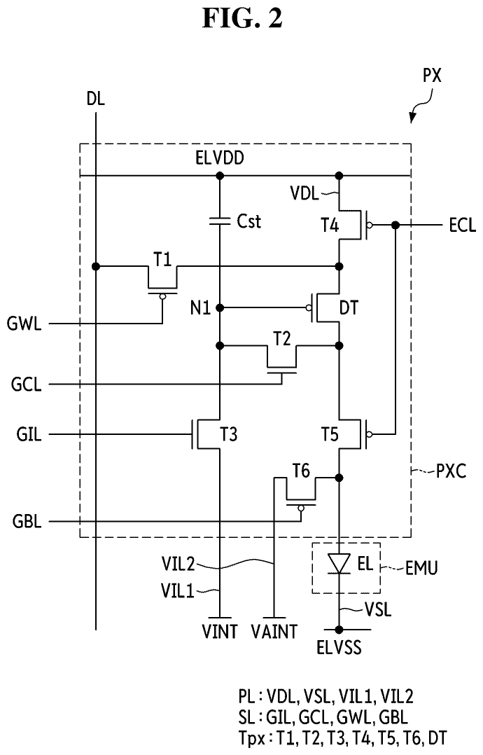

FIG. 2 is an equivalent circuit diagram illustrating a pixel according to one embodiment.

In FIG. 2, an embodiment in which scan lines SL connected to each pixel PX include an initialization scan line GIL, a control scan line GCL, a write scan line GWL, an emission control line ECL, and a bias scan line GBL will be disclosed. Further, in FIG. 2, an embodiment in which power lines PL connected to each pixel PX include a first power line VDL, a second power line VSL, a first initialization voltage line VIL1, and a second initialization voltage line VIL2 will be disclosed. However, the embodiments are not limited thereto. For example, the type or number of the scan lines SL and the power lines PL connected to each pixel PX may vary depending on the type or structure of the pixel PX.

Referring to FIG. 2, the pixel PX may include a light-emitting unit EMU including at least one light-emitting element EL and a pixel circuit PXC (also referred to as “pixel driver”) connected to the light-emitting unit EMU.

The light-emitting element EL may be connected between the second power line VSL to which a second driving voltage ELVSS is applied and the pixel circuit PXC. The light-emitting element EL, which is a light source of the pixel PX, may emit light in response to a driving current supplied from the pixel circuit PXC.

The light-emitting element EL may be an organic light-emitting diode but is not limited thereto. For example, the light-emitting element EL may be an inorganic light-emitting element, a quantum dot light-emitting element, or another type of light-emitting element.

The pixel circuit PXC may control the light-emitting timing and luminance of the light-emitting element EL by controlling the driving current supplied to the light-emitting element EL. The pixel circuit PXC may include pixel transistors Tpx and a capacitor Cst. The pixel transistors Tpx may include a driving transistor DT and at least one switch element. In one embodiment, the pixel transistors Tpx may include first to sixth transistors T1, T2, T3, T4, T5, and T6 as the switch elements.

The driving transistor DT may include a gate electrode connected to a first node N1, a first electrode connected to the first power line VDL via the fourth transistor T4, and a second electrode connected to the light-emitting unit EMU via the fifth transistor T5. One of the first electrode and the second electrode may be a source electrode and the other may be a drain electrode. The driving transistor DT may control a source-drain current (hereinafter referred to as “driving current”) flowing between the first electrode and the second electrode according to the voltage (e.g., the voltage of the first node N1 corresponding to the voltage of the data signal) applied to the gate electrode of the driving transistor DT.

The first transistor T1 may include the gate electrode connected to the write scan line GWL, the first electrode connected to the data line DL, and the second electrode connected to the first electrode of the driving transistor DT. The first transistor T1 may be turned on in response to the write scan signal supplied from the write scan line GWL to connect the first electrode of the driving transistor DT to the data line DL. When the first transistor T1 is turned on, the voltage of the data signal supplied from the data line DL may be supplied to the first electrode of the driving transistor DT.

The second transistor T2 may include the gate electrode connected to the control scan line GCL, the first electrode connected to the second electrode of the driving transistor DT, and the second electrode connected to the first node N1. The second transistor T2 may be turned on in response to a control scan signal supplied to the control scan line GCL to connect the second electrode and the gate electrode of the driving transistor DT. When the second transistor T2 is turned on, the driving transistor DT may be driven as a diode.

The third transistor T3 may include the gate electrode connected to the initialization scan line GIL, the first electrode connected to the first node N1, and the second electrode connected to the first initialization voltage line VIL1. The third transistor T3 may be turned on in response to an initialization scan signal supplied from the initialization scan line GIL to connect the first node N1 to the first initialization voltage line VIL1. When the third transistor T3 is turned on, the first initialization voltage VINT supplied from the first initialization voltage line VIL1 may be supplied to the first node N1.

The fourth transistor T4 may include the gate electrode connected to the emission control line ECL, the first electrode connected to the first power line VDL, and the second electrode connected to the first electrode of the driving transistor DT. The fourth transistor T4 may be turned on in response to the emission control signal supplied from the emission control line ECL to connect the first electrode of the driving transistor DT to the first power line VDL to which the first driving voltage ELVDD is supplied. When the fourth transistor T4 is turned on, the first driving voltage ELVDD may be supplied to the first electrode of the driving transistor DT.

The fifth transistor T5 may include the gate electrode connected to the emission control line ECL, the first electrode connected to the second electrode of the driving transistor DT, and the second electrode connected to the light-emitting element EL. The fifth transistor T5 may be turned on in response to the emission control signal supplied from the emission control line ECL to connect the driving transistor DT to the light-emitting element EL. When both the fourth transistor T4 and the fifth transistor T5 are turned on, the driving current having a magnitude corresponding to the voltage (e.g., the voltage of the first node N1) of the gate electrode of the driving transistor DT may flow through the light-emitting element EL.

The sixth transistor T6 may include the gate electrode connected to the bias scan line GBL, the first electrode connected to the anode electrode of the light-emitting element EL, and the second electrode connected to the second initialization voltage line VIL2. The sixth transistor T6 may be turned on in response to a bias scan signal supplied from the bias scan line GBL to connect the anode electrode of the light-emitting element EL to the second initialization voltage line VIL2. When the sixth transistor T6 is turned on, a second initialization voltage VAINT supplied from the second initialization voltage line VIL2 may be supplied to the anode electrode of the light-emitting element EL.

The capacitor Cst may be connected between the first node N1 and the first power line VDL. The capacitor Cst may be charged with a voltage corresponding to the voltage of the first node N1.

In one embodiment, some of the pixel transistors Tpx and some others thereof may be formed of transistors of different types. For example, as shown in FIG. 2, the driving transistor DT and the first, fourth, fifth, and sixth transistors T1, T4, T5, and T6 may be formed as P-type transistors (e.g., P-type MOSFETs), and the second and third transistors T2 and T3 may be formed as N-type transistors (e.g., N-type MOSFETs). In one embodiment, the P-type transistors and the N-type transistors may include different semiconductor materials. For example, the active layer of each of the P-type transistors may be made of polysilicon, and the active layer of each of the N-type transistors may be made of an oxide semiconductor. In one embodiment, transistors including different semiconductor materials may be disposed in different layers on the substrate 110.

However, the embodiments are not limited thereto. For example, the pixel transistors Tpx may be formed as transistors of the same type and may include the same semiconductor material. For example, the driving transistor DT and the first to sixth transistors T1, T2, T3, T4, T5, and T6 may be formed as P-type transistors including polysilicon or may be formed as N-type transistors including an oxide semiconductor. In addition, the types or materials of the pixel transistors Tpx may be variously changed depending on embodiments.

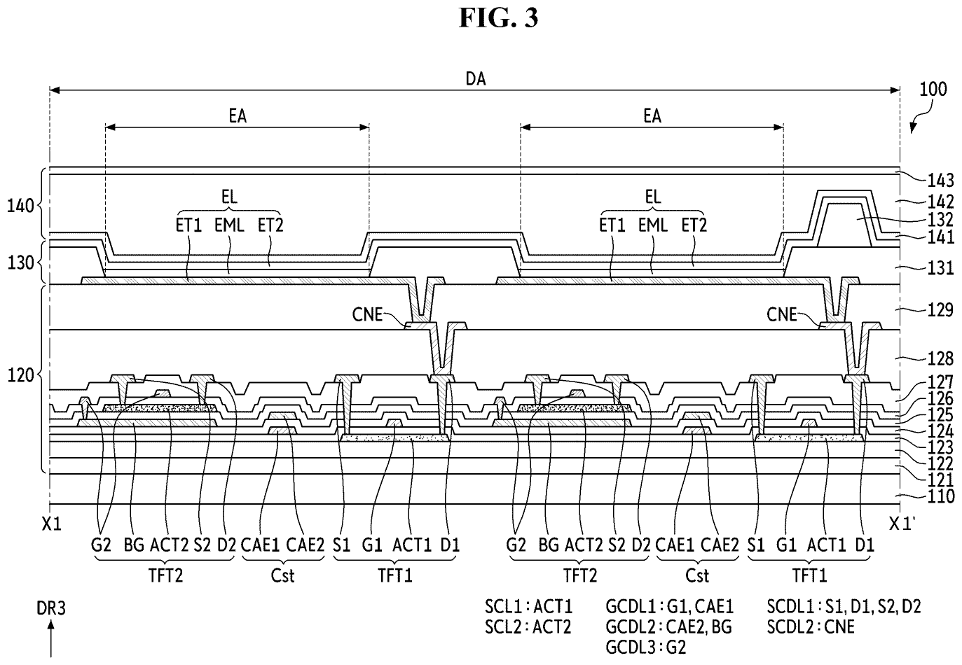

FIG. 3 is a cross-sectional view illustrating a display device according to one embodiment. For example, FIG. 3 illustrates an example of a cross-section of a portion of the display area DA corresponding to line X1-X1′ of FIG. 1.

Referring to FIG. 3 in addition to FIGS. 1 and 2, the display device 100 may include the substrate 110, a circuit layer 120, a light-emitting element layer 130, and an encapsulation layer 140 disposed on the substrate 110. In one embodiment, the circuit layer 120, the light-emitting element layer 130, and the encapsulation layer 140 may be sequentially disposed or stacked on the substrate 110 along the third direction DR3. In describing the embodiments, the circuit layer 120 and the light-emitting element layer 130 are separately described, but the embodiments are not limited thereto. For example, the circuit layer 120 and the light-emitting element layer 130 may be integrated on the substrate 10. The encapsulation layer 140 may be replaced with another encapsulation member (e.g., an upper substrate or the like).

The substrate 110 may be a base layer for forming the display device 100. For example, the substrate 110 may form a support for a display panel including the pixels PX.

In one embodiment, the substrate 110 may be a flexible substrate capable of transformation such as bending, folding, or rolling, and may be bent in the bending area BA of FIG. 1. The substrate 110 may include an insulating material such as a polymer resin. For example, the substrate 110 may be made of polyimide or another insulating material.

However, the embodiments are not limited thereto. For example, the substrate 110 may be a substrate including an insulating material such as glass or the like, and having rigid characteristics, and may not be bent.

The circuit layer 120 may include circuit elements (e.g., the pixel transistors Tpx and the capacitors Cst) of the pixels PX and wires (e.g., the scan lines SL, the emission control lines ECL, the data lines DL, and the power lines PL) connected to the pixels PX. For example, the circuit layer 120 may be a thin film transistor layer or a panel circuit layer of a display panel including the pixels PX.

FIG. 3 shows, among elements that may be disposed in the circuit layer 120 in the display area DA, a first pixel transistor TFT1 (also referred to as “first thin film transistor”), a second pixel transistor TFT2 (also referred to as “second thin film transistor”), and the capacitor Cst that are included in the pixel circuit PXC of each pixel PX. Further, FIG. 3 shows the display device 100 of the structure in which a first active layer ACT1 of the first pixel transistor TFT1 and a second active layer ACT2 of the second pixel transistor TFT2 are disposed in different layers in the circuit layer 120. However, the embodiments are not limited thereto. For example, the active layers of the pixel transistors Tpx included in the pixel circuit PXC may be disposed in the same layer.

In one embodiment, the first pixel transistor TFT1 may represent a first type transistor (e.g., a P-type transistor) including a first semiconductor material (e.g., polysilicon) among the pixel transistors Tpx constituting each of the pixel circuits PXC. FIG. 3 illustrates, as the first pixel transistor TFT1, a first type transistor connected to the light-emitting element EL of the pixel PX through a connection electrode CNE. For example, the first pixel transistor TFT1 of FIG. 3 may be the fifth transistor T5 or the sixth transistor T6 of FIG. 2 but is not limited thereto.

In one embodiment, the second pixel transistor TFT2 may represent a second type transistor (e.g., an N-type transistor) including a second semiconductor material (e.g., an oxide semiconductor) among the pixel transistors Tpx constituting each of the pixel circuits PXC. For example, the second pixel transistor TFT2 of FIG. 3 may be the second transistor T2 or the third transistor T3 of FIG. 2 but is not limited thereto.

Cross sections of the pixels PX may be variously changed according to each of the pixels PX and the type or structure of the display device 100 including the pixel PX. For example, positions and order of formation of the first pixel transistor TFT1, the second pixel transistor TFT2, and the capacitor Cst may vary according to embodiments.

The circuit layer 120 may include semiconductor layers (or a single semiconductor layer) for forming circuit elements, wires or the like, conductive layers, and insulating layers disposed between and/or around the semiconductor layers and the conductive layers. For example, the circuit layer 120 may include a first semiconductor layer SCL1 (e.g., a polysilicon semiconductor layer), a first insulating layer 123, a first conductive layer GCDL1 (e.g., a first gate conductive layer), a second insulating layer 124, a second conductive layer GCDL2 (e.g., a second gate conductive layer), a third insulating layer 125, a second semiconductor layer SCL2 (e.g., an oxide semiconductor layer), a fourth insulating layer 126, a third conductive layer GCDL3 (e.g., a third gate conductive layer), a fifth insulating layer 127, a fourth conductive layer SCDL1 (e.g., a first data conductive layer or a first source-drain conductive layer), and a sixth insulating layer 128 that are sequentially disposed or stacked above the substrate 110 with reference to the third direction DR3.

In one embodiment, the circuit layer 120 may not include the second semiconductor layer SCL2 or the like. For example, when the pixel transistors Tpx of each of the pixels PX include active layers disposed in the same layer, the circuit layer 120 may not include the second semiconductor layer SCL2, the fourth insulating layer 126 and/or the third conductive layer GCDL3.

In one embodiment, the circuit layer 120 may further include at least one conductive layer and at least one insulating layer disposed on the sixth insulating layer 128. For example, the circuit layer 120 may further include a fifth conductive layer SCDL2 (e.g., a second data conductive layer or a second source-drain conductive layer) and a seventh insulating layer 129 that are sequentially disposed on the sixth insulating layer 128.

In one embodiment, the circuit layer 120 may further include at least one insulating layer and/or at least one conductive layer disposed between the substrate 110 and the first semiconductor layer SCL1. For example, the circuit layer 120 may include a barrier layer 121 and a buffer layer 122 that are sequentially disposed or stacked between the substrate 110 and the first semiconductor layer SCL1. In one embodiment, the circuit layer 120 may further include a lower conductive layer (not shown) disposed between the barrier layer 121 and the buffer layer 122. The lower conductive layer may include at least one wire and/or conductive pattern (e.g., a conductive light blocking layer). At least some of the insulating layers disposed in the display area DA in the circuit layer 120 may also be disposed in the non-display area NA.

Each of the barrier layer 121 and the buffer layer 122 may include at least one inorganic insulating layer containing an inorganic insulating material (e.g., silicon nitride, silicon oxide, silicon oxynitride, titanium oxide, aluminum oxide, or another inorganic insulating material). The barrier layer 121 and the buffer layer 122 may protect the pixels PX from moisture permeating through the substrate 110 that is susceptible to moisture permeation. The material of the barrier layer 121 and the buffer layer 122 may be variously changed according to embodiments.

The first pixel transistor TFT1, the second pixel transistor TFT2, and the capacitor Cst may be disposed on one surface of the substrate 110 on which the barrier layer 121 and/or the buffer layer 122 is disposed.

The first pixel transistor TFT1 may include the first active layer ACT1 and a first gate electrode G1. In one embodiment, the first pixel transistor TFT1 may further include a first source electrode S1 and a first drain electrode D1 connected to the first active layer ACT1. In another embodiment, the first pixel transistor TFT1 may not include a separate first source electrode S1 and/or a separate first drain electrode D1 and may include a source electrode and/or a drain electrode formed integrally with the source region and/or the drain region of the first active layer ACT1.

The second pixel transistor TFT2 may include the second active layer ACT2 and a second gate electrode G2. In one embodiment, the second pixel transistor TFT2 may further include a bottom-gate electrode BG. In one embodiment, the second pixel transistor TFT2 may further include a second source electrode S2 and a second drain electrode D2 connected to the second active layer ACT2. In another embodiment, the second pixel transistor TFT2 may not include the second source electrode S2 and/or the second drain electrode D2 that are provided additionally but may include a source electrode and/or a drain electrode integrally formed with a source region and/or a drain region of the second active layer ACT2.

The capacitor Cst may include a first capacitor electrode CAE1 and a second capacitor electrode CAE2. The first capacitor electrode CAE1 and the second capacitor electrode CAE2 may overlap each other in a plan view with at least one insulating film (e.g., the second insulating layer 124) interposed therebetween.

Specifically, the first semiconductor layer SCL1 may be disposed on the buffer layer 122 which is disposed on the barrier layer 121. The first semiconductor layer SCL1 may include the first active layer ACT1 of the first pixel transistor TFT1. For example, the first semiconductor layer SCL1 may include the active layers of the first type transistors among the pixel transistors Tpx.

The first active layer ACT1 may include a first semiconductor material (e.g., polysilicon). The first active layer ACT1 may include a channel region overlapping the first gate electrode G1, and a source region and a drain region located on both sides of the channel region. In one embodiment, the source region and the drain region of the first active layer ACT1 may be connected to the first source electrode S1 and the first drain electrode D1, respectively. In another embodiment, the source region and/or the drain region of the first active layer ACT1 may be the source electrode and/or the drain electrode of the first pixel transistor TFT1, respectively.

The first insulating layer 123 may be disposed on the first semiconductor layer SCL1. The first insulating layer 123 may cover the first semiconductor layer SCL1.

The first conductive layer GCDL1 may be disposed on the first insulating layer 123. The first conductive layer GCDL1 may include the first gate electrode G1 of the first pixel transistor TFT1. The first gate electrode G1 may be disposed on the first active layer ACT1 to overlap a part (e.g., the channel region) of the first active layer ACT1.

In one embodiment, the first conductive layer GCDL1 may further include at least one wire (or a part of the at least one wire), a conductive pattern (e.g., a bridge pattern), and/or a capacitor electrode. For example, the first conductive layer GCDL1 may further include the first capacitor electrode CAE1 of the capacitor Cst.

The second insulating layer 124 may be disposed on the first conductive layer GCDL1. The second insulating layer 124 may cover the first conductive layer GCDL1.

The second conductive layer GCDL2 may be disposed on the second insulating layer 124. The second conductive layer GCDL2 may include one electrode of the capacitor Cst, for example, the second capacitor electrode CAE2. In one embodiment, the second conductive layer GCDL2 may further include at least one electrode, a wire (or a part of the at least one wire), and/or a conductive pattern (e.g., a bridge pattern). For example, the second conductive layer GCDL2 may further include the bottom-gate electrode BG of the second pixel transistor TFT2. In one embodiment, the bottom-gate electrode BG of the second pixel transistor TFT2 may be connected to the second gate electrode G2 of the second pixel transistor TFT2, but the present disclosure is not limited thereto.

The third insulating layer 125 may be disposed on the second conductive layer GCDL2. The third insulating layer 125 may cover the second conductive layer GCDL2. The second semiconductor layer SCL2 may be disposed on the third insulating layer 125. The second semiconductor layer SCL2 may include the second active layer ACT2 of the second pixel transistor TFT2. For example, the second semiconductor layer SCL2 may include the active layers of the second type transistors among the pixel transistors Tpx. The second active layer ACT2 may include a second semiconductor material (e.g., an oxide semiconductor) different from the first semiconductor material. For example, the second active layer ACT2 may include indium-gallium-zinc oxide (IGZO), indium-gallium-zinc-tin oxide (IGZTO), indium-gallium-tin oxide (IGTO), indium-gallium oxide (IGO), or other oxide semiconductors.

The second active layer ACT2 may include a channel region overlapping the second gate electrode G2, and a source region and a drain region located on both sides of the channel region. In one embodiment, the source region and the drain region of the second active layer ACT2 may be connected to the second source electrode S2 and the second drain electrode D2, respectively. In another embodiment, the source region and/or the drain region of the second active layer ACT2 may be the source electrode and/or the drain electrode of the second pixel transistor TFT2, respectively.

The fourth insulating layer 126 may be disposed on the second semiconductor layer SCL2. The fourth insulating layer 126 may cover the second semiconductor layer SCL2.

The third conductive layer GCDL3 may be disposed on the fourth insulating layer 126. The third conductive layer GCDL3 may include the second gate electrode G2 of the second pixel transistor TFT2. The second gate electrode G2 may be disposed on the second active layer ACT2 to overlap a part (e.g., the channel region) of the second active layer ACT2. In one embodiment, the third conductive layer GCDL3 may further include at least one wire (or a part of the at least one wire), a conductive pattern (e.g., a bridge pattern), and/or a capacitor electrode.

The fifth insulating layer 127 may be disposed on the third conductive layer GCDL3. The fifth insulating layer 127 may cover the third conductive layer GCDL3.

The fourth conductive layer SCDL1 may be disposed on the fifth insulating layer 127. The fourth conductive layer SCDL1 may include the first source electrode S1 and the first drain electrode D1 of the first pixel transistor TFT1 (or at least one bridge pattern connected to the first source electrode S1 and/or the first drain electrode D1 of the first pixel transistor TFT1), and the second source electrode S2 and the second drain electrode D2 of the second pixel transistor TFT2 (or at least one bridge pattern connected to the second source electrode S2 and/or the second drain electrode D2 of the second pixel transistor TFT2).

The first source electrode S1 may be connected to the source region of the first active layer ACT1. For example, the first source electrode S1 may be connected to the source region of the first active layer ACT1 through a contact hole formed through the first insulating layer 123, the second insulating layer 124, the third insulating layer 125, the fourth insulating layer 126, and the fifth insulating layer 127.

The first drain electrode D1 may be connected to the drain region of the first active layer ACT1. For example, the first drain electrode D1 may be connected to the drain region of the first active layer ACT1 through a contact hole formed through the first insulating layer 123, the second insulating layer 124, the third insulating layer 125, the fourth insulating layer 126, and the fifth insulating layer 127.

The second source electrode S2 may be connected to the source region of the second active layer ACT2. For example, the second source electrode S2 may be connected to the source region of the second active layer ACT2 through a contact hole formed through the fourth insulating layer 126 and the fifth insulating layer 127.

The second drain electrode D2 may be connected to the drain region of the second active layer ACT2. For example, the second drain electrode D2 may be connected to the drain region of the second active layer ACT2 through a contact hole formed through the fourth insulating layer 126 and the fifth insulating layer 127.

In one embodiment, the fourth conductive layer SCDL1 may further include at least one wire (or a part of the at least one wire), and/or a conductive pattern (e.g., a bridge pattern). For example, a part of the data lines DL located in the display area DA may be provided or disposed in the fourth conductive layer SCDL1. In one embodiment, the other part of the data lines DL located in the non-display area NA may be disposed in another conductive layer (e.g., the first conductive layer GCDL1 or the second conductive layer GCDL2).

The sixth insulating layer 128 may be disposed on the fourth conductive layer SCDL1. The sixth insulating layer 128 may cover the fourth conductive layer SCDL1.

The fifth conductive layer SCDL2 may be disposed on the sixth insulating layer 128. The fifth conductive layer SCDL2 may include the connection electrode CNE. The connection electrode CNE may be connected to one electrode (e.g., the first drain electrode D1) of the first pixel transistor TFT1 through a contact hole or via hole formed through the sixth insulating layer 128. In one embodiment, the fifth conductive layer SCDL2 may further include at least one wire (or a part of the at least one wire), and/or a conductive pattern (e.g., a bridge pattern). For example, a part of at least one power line PL located in the display area DA may be provided or disposed in the fifth conductive layer SCDL2.

The electrodes, the conductive patterns, and/or the wires included in the first conductive layer GCDL1, the second conductive layer GCDL2, the third conductive layer GCDL3, the fourth conductive layer SCDL1, and the fifth conductive layer SCDL2 may include at least one conductive material (e.g., at least one of molybdenum (Mo), aluminum (Al), chromium (Cr), gold (Au), silver (Ag), titanium (Ti), nickel (Ni), neodymium (Nd), copper (Cu), or other metals, an alloy thereof, or other conductive materials), and may have a single-layer or multilayer structure. At least two conductive layers among the first conductive layer GCDL1, the second conductive layer GCDL2, the third conductive layer GCDL3, the fourth conductive layer SCDL1, and the fifth conductive layer SCDL2 may include the same material or may include different materials.

In one embodiment, each of the electrodes, the conductive patterns, and/or the wires provided in the first conductive layer GCDL1, the second conductive layer GCDL2, and the third conductive layer GCDL3 may include molybdenum (Mo) or other metal materials. In one embodiment, each of the electrodes, the conductive patterns, and/or the wires provided in the fourth conductive layer SCDL1 and the fifth conductive layer SCDL2 may be formed in a triple-layer structure of titanium (Ti)/aluminum (Al)/titanium (Ti).

However, the embodiments are not limited thereto. For example, the material and structure of each of the first conductive layer GCDL1, the second conductive layer GCDL2, the third conductive layer GCDL3, the fourth conductive layer SCDL1, and the fifth conductive layer SCDL2 may be variously changed depending on embodiments.

The seventh insulating layer 129 may be disposed on the fifth conductive layer SCDL2. The seventh insulating layer 129 may cover the fifth conductive layer SCDL2.

Each of the first insulating layer 123, the second insulating layer 124, the third insulating layer 125, the fourth insulating layer 126, the fifth insulating layer 127, the sixth insulating layer 128, and the seventh insulating layer 129 may include at least one insulating material and may have a single-layer or multilayer structure. At least two insulating layers among the first insulating layer 123, the second insulating layer 124, the third insulating layer 125, the fourth insulating layer 126, the fifth insulating layer 127, the sixth insulating layer 128, and the seventh insulating layer 129 may include the same material or may include different materials.

In one embodiment, the first insulating layer 123, the second insulating layer 124, the third insulating layer 125, the fourth insulating layer 126, and the fifth insulating layer 127 may include an inorganic insulating layer including an inorganic insulating material (e.g., silicon nitride, silicon oxide, silicon oxynitride, titanium oxide, aluminum oxide, or another inorganic insulating material). In one embodiment, the sixth insulating layer 128 and the seventh insulating layer 129 may include an organic insulating material (e.g., acryl resin, epoxy resin, phenolic resin, polyamide resin, polyimide resin, or other organic insulating materials). The top surfaces of the sixth insulating layer 128 and the seventh insulating layer 129 may be substantially flat. For example, the top surface of the circuit layer 120 may be flattened by the sixth insulating layer 128 and the seventh insulating layer 129.

The light-emitting element layer 130 may be disposed on the circuit layer 120 and may be positioned in the display area DA. For example, the light-emitting element layer 130 may be disposed on the circuit layer 120 in the display area DA.

The light-emitting element layer 130 may include the light-emitting elements EL of the pixels PX. For example, the light-emitting element layer 130 may include a pixel defining film 131 (also referred to as “bank”) that separates emission areas EA of the respective pixels PX, and the light-emitting element EL located in the emission areas EA of each pixel PX. In one embodiment, the light-emitting element layer 130 may further include a spacer 132 disposed on a part of the pixel defining film 131.

In one embodiment, each light-emitting element EL may be connected to at least one transistor (e.g., the first pixel transistor TFT1) included in the corresponding pixel PX through the connection electrode CNE. In another embodiment, the pixel PX may not include the connection electrode CNE, and the light-emitting element EL may be directly connected to the at least one transistor without the connection electrode CNE.

Each light-emitting element EL may include a first electrode ET1 (e.g., an anode electrode) and a second electrode ET2 (e.g., a cathode electrode) facing each other, and a light-emitting layer EML disposed between the first electrode ET1 and the second electrode ET2. In one embodiment, the first electrode ET1, the light-emitting layer EML, and the second electrode ET2 may be sequentially disposed or stacked on the circuit layer 120.

In one embodiment, the light-emitting element EL may further include at least one intermediate layer. As an example, the light-emitting element EL may further include a first intermediate layer (e.g., hole layer including a hole transport layer) interposed between the first electrode ET1 and the light-emitting layer EML, and a second intermediate layer (e.g., an electron layer including an electron transport layer) interposed between the light-emitting layer EML and the second electrode ET2.

Although FIG. 3 discloses an embodiment in which the light-emitting element EL includes a single light-emitting layer EML, embodiments are not limited thereto. For example, the light-emitting element EL may have a tandem structure in which at least two light-emitting layers (e.g., the light-emitting layer EML of FIG. 3 and an additional light-emitting layer overlapping the light-emitting layer EML) overlapping each other in each emission area EA. Further, the light-emitting element EL having the tandem structure may further include a charge generation layer interposed between the at least two light-emitting layers.

The first electrode ET1 of the light-emitting element EL may be disposed on the circuit layer 120. For example, the first electrode ET1 may be disposed on the seventh insulating layer 129 to correspond to each emission area EA. The first electrode ET1 may be connected to the connection electrode CNE through the contact hole or the via hole formed through the seventh insulating layer 129.

The first electrode ET1 may include a conductive material. In one embodiment, the first electrode ET1 may include a metal material having high reflectivity. For example, the first electrode ET1 may have a single-layer structure of molybdenum (Mo), titanium (Ti), copper (Cu) or aluminum (Al), or may have a multilayer structure (e.g., ITO/Mg, ITO/MgF (or ITO/MgF₂), ITO/Ag, and ITO/Ag/ITO) including indium-tin-oxide (ITO), indium-zinc-oxide (IZO), zinc oxide (ZnO), indium oxide (In₂O₃) and silver (Ag), magnesium (Mg), aluminum (Al), platinum (Pt), lead (Pb), gold (Au), or nickel (Ni).

The light-emitting layer EML of the light-emitting element EL may include a high molecular material or a low molecular material. Light emitted from the light-emitting layer EML may contribute to image display. In one embodiment, the light-emitting layer EML may be provided for each pixel PX, and the light-emitting layer EML of each pixel PX may emit visible light of a color corresponding to the corresponding pixel PX. In another embodiment, the light-emitting layer EML may be a common layer shared by the pixels PX of different colors, and a wavelength conversion layer and/or color filters corresponding to the color (or wavelength band) of light desired to be emitted from each pixel PX may be arranged in the emission areas EA of at least some of the pixels PX.

The second electrode ET2 of the light-emitting element EL may include a conductive material. In one embodiment, the second electrode ET2 may be a common layer formed across the entire display area DA to cover the light-emitting layer EML and the pixel defining film 131. In one embodiment, the second electrode ET2 may include transparent conductive oxide (TCO) such as ITO or IZO capable of transmitting light or a semi-transmissive conductive material such as magnesium (Mg), silver (Ag), or an alloy of magnesium (Mg) and silver (Ag).

The pixel defining film 131 may have an opening corresponding to each of the emission areas EA and may surround the emission areas EA. For example, the pixel defining film 131 may be formed to cover an edge of the first electrode ET1 of the light-emitting element EL and may include an opening exposing the remaining portion of the first electrode ET1. A region where the exposed first electrode ET1 and the light-emitting layer EML overlap (or a region including the same) may be defined as the emission area EA of each pixel PX.

In one embodiment, the pixel defining film 131 may include an organic insulating material. For example, the pixel defining film 131 may include acrylic resin, epoxy resin, phenolic resin, polyamide resin, polyimide resin, unsaturated polyester resin, polyphenylene ether resin, polyphenylenesulfide resin, benzocyclobutene (BCB), or other organic insulating materials.

The spacer 132 may be disposed on a part of the pixel defining film 131. In one embodiment, the spacer 132 may include at least one organic insulating layer containing an organic insulating material. The spacer 132 may include the same material as the pixel defining film 131 or may include a different material from the pixel defining film 131.

The pixel defining film 131 and the spacer 132 may be integrated with each other and formed as a single pattern, or maybe patterns formed individually and/or sequentially. For example, the pixel defining film 131 and the spacer 132 may be sequentially formed through individual mask processes or may be simultaneously and/or integrally formed using a halftone mask. In this case, when the pixel defining film 131 and the spacer 132 are formed integrally with each other, the pixel defining film 131 and the spacer 132 may be regarded as different parts of one pattern.

The encapsulation layer 140 may be disposed on the light-emitting element layer 130. The encapsulation layer 140 may cover the light-emitting element layer 130 in the display area DA and may extend to the non-display area NA to be in contact with the circuit layer 120. For example, the encapsulation layer 140 may be disposed in the display area DA to cover the light-emitting element layer 130, and the end of the encapsulation layer 140 may be disposed in a portion (e.g., the first non-display area NA1) of the non-display area NA disposed adjacent to the display area DA. The encapsulation layer 140 may block the permeation of oxygen or moisture into the light-emitting element layer 130 and may mitigate electrical and/or physical impacts to the circuit layer 120 and the light-emitting element layer 130.

In one embodiment, the encapsulation layer 140 may be a multiple encapsulation layer including a first encapsulation layer 141, a second encapsulation layer 142, and a third encapsulation layer 143 sequentially disposed on the light-emitting element layer 130. The first encapsulation layer 141 and the third encapsulation layer 143 may be inorganic encapsulation layers containing an inorganic material, and the second encapsulation layer 142 may be an organic encapsulation layer containing an organic material. Each of the first encapsulation layer 141, the second encapsulation layer 142, and the third encapsulation layer 143 may be formed as a single layer or multiple layers.

In one embodiment, the display device 100 may further include an additional element disposed on the encapsulation layer 140. For example, the display device 100 may further include at least one of a sensor layer (e.g., a touch sensor layer), an optical layer (e.g., an anti-reflection layer including a polarizing layer and/or a color filter layer), or a protective layer (e.g., a window or a protective film) that are disposed on the encapsulation layer 140.

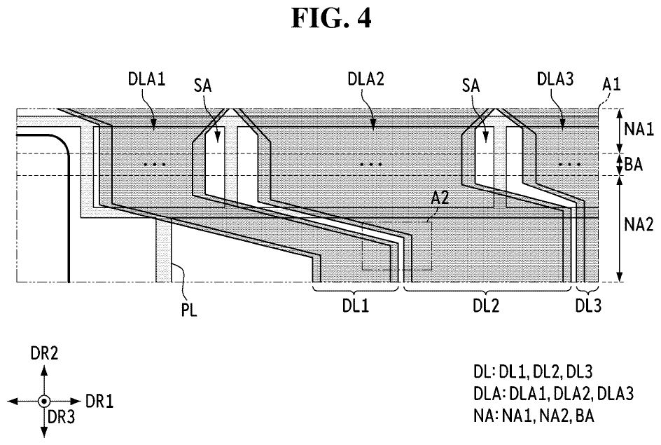

FIG. 4 is a plan view illustrating area A1 of FIG. 1 in detail. For example, FIG. 4 shows one embodiment of a part of the data lines DL disposed in area A1 of FIG. 1 and a part of the power line PL disposed around the data lines DL.

Referring to FIGS. 1 to 4, the data lines DL may be connected between the pixels PX in the display area DA and the driving circuit 150 in the non-display area NA. For example, on the substrate 110, the data lines DL may extend from the display area DA where the pixels PX are disposed to the second non-display area NA2 on which the driving circuit 150 is mounted via the first non-display area NA1 and the bending area BA.

The non-display area NA may include a data line area DLA in which the data lines DL are disposed. The data line area DLA may include a data spider area or a data fan-out area where the data lines DL extend in a spider shape or a fan-out shape.

In one embodiment, the data line area DLA may include a plurality of wiring areas DLA1, DLA2, and DLA3 (e.g., sub-areas of the data line area DLA) spaced apart from each other with an isolation area SA (also referred to as “separation area”) disposed between adjacent wiring areas in at least a part of the non-display area NA, and the plurality of data lines DL may be disposed in each of the plurality of wiring areas DLA1, DLA2, and DLA3. For example, each of the data lines DL may be disposed in one of the plurality of wiring areas DLA1, DLA2, and DLA3.

In one embodiment, the data line area DLA may include a first wiring area DLA1 in which the first data lines DL1 are disposed and a second wiring area DLA2 in which the second data lines DL2 are disposed. In one embodiment, the data line area DLA may further include at least one wiring area including the third wiring area DLA3 in which the third data lines DL3 are disposed.

The first wiring area DLA1, the second wiring area DLA2, and the third wiring area DLA3 may be sequentially disposed along the first direction DR1. For example, the first wiring area DLA1, the second wiring area DLA2, and the third wiring area DLA3 may be sequentially disposed along the first direction DR1 in each of the first non-display area NA1, the bending area BA, and the second non-display area NA2.

The isolation area SA may be disposed between adjacent wiring areas sequentially disposed in the first direction DR1. In one embodiment, the isolation area SA may be disposed in a part of the non-display area NA including the bending area BA. For example, in a part of the non-display area NA including the bending area BA, the isolation area SA may be disposed between the first wiring area DLA1 and the second wiring area DLA2, and between the second wiring area DLA2 and the third wiring area DLA3.

The first wiring area DLA1 and the second wiring area DLA2 may be sequentially disposed along the first direction DR1. The isolation area SA may be disposed between the first wiring area DLA1 and the second wiring area DLA2. Similarly, the second wiring area DLA2 and the third wiring area DLA3 may be sequentially disposed along the first direction DR1. The isolation area SA may be disposed between the second wiring area DLA2 and the third wiring area DLA3.

The data lines DL may be distributed and disposed in the plurality of wiring areas DLA1, DLA2, and DLA3. For example, the first data lines DL1 may be disposed consecutively or sequentially along the first direction DR1 in the first wiring area DLA1. The second data lines DL2 may be disposed consecutively or sequentially along the first direction DR1 in the second wiring area DLA2. The third data lines DL3 may be disposed consecutively or sequentially along the first direction DR1 in the third wiring area DLA3.

The data lines DL may not be disposed in the isolation area SA. For example, in a part of the non-display area NA, the first data lines DL1 and the second data lines DL2 may be disposed with the isolation area SA which is disposed between the first wiring area DLA1 and the second wiring area DLA2. In an embodiment, in another part of the non-display area NA, the first data lines DL1 and the second data lines DL2 may be disposed consecutively or adjacently. Similarly, in a part of the non-display area NA, the second data lines DL2 and the third data lines DL3 may be disposed with the isolation area SA which is disposed between the second wiring area DLA2 and the third wiring area DLA3. In an embodiment, in another part of the non-display area NA, the second data lines DL2 and the third data lines DL3 may be disposed consecutively or adjacently.

In one embodiment, the power line PL may be disposed in the isolation areas SA. For example, the power line PL may be disposed in the display area DA and the non-display area NA on the substrate 110 and may be disposed in the isolation area SA. The power line PL may be connected to the pixels PX and transmit the driving voltage required for driving the pixels PX. For example, the power line PL may be connected between the pixels PX and the power pad located in the pad area PA.

Although only one power line PL is shown in FIG. 4, embodiments are not limited thereto. For example, the plurality of power lines PL (e.g., the plurality of power lines PL connected to the pixels PX) may be distributed and disposed in the isolation areas SA. Further, FIG. 4 shows an approximate shape or location of the power line PL, and the shape, size, and/or location of the power line PL may be variously changed depending on embodiments.

A part of the power line PL may overlap the data lines DL. At the part where the power line PL and the data lines DL overlap, the power line PL and the data lines DL may be disposed in different conductive layers on the substrate 110. For example, in at least one of the first non-display area NA1 and the second non-display area NA2, the data lines DL may be alternately disposed in the first conductive layer GCDL1 and the second conductive layer GCDL2 of the circuit layer 120, and the power line PL may be disposed in at least one of the third conductive layer GCDL3, the fourth conductive layer SCDL1, or the fifth conductive layer SCDL2 of the circuit layer 120.

The other part of the power line PL may not overlap the data lines DL. At the part where the power line PL and the data lines DL do not overlap, the power line PL and the data lines DL may be disposed in different conductive layers or in the same conductive layer on the substrate 110. For example, in the bending area BA, the data lines DL and the power line PL may be disposed in the same conductive layer (e.g., the fourth conductive layer SCDL1 or the fifth conductive layer SCDL2). In the bending area BA, when the data lines DL and the power line PL are disposed in the same layer, the structure or thickness of the bending area BA may be reduced or minimized, and the flexibility of the bending area BA may be increased.

The positions or mutual arrangement structure of the data lines DL and the power line PL is not limited to the above-described embodiment. For example, the positions or mutual arrangement structure of the data lines DL and the power line PL may be variously changed depending on embodiments.

In one embodiment, the wiring areas DLA1, DLA2, and DLA3 may have different widths for each part or each location. The data lines DL may be arranged at intervals corresponding to the widths of the wiring areas DLA1, DLA2, and DLA3. For example, the data lines DL may be arranged at intervals corresponding to the widths or shapes of the wiring areas DLA1, DLA2, and DLA3.

In one embodiment, the data lines DL may include straight portions extending in the second direction DR2, and diagonal portions extending in a diagonal direction intersecting the first direction DR1 and the second direction DR2.

The gap between the data lines DL may be adjusted or changed for each part or each location depending on the position or extension direction of the data lines DL. For example, the diagonal portions of the data lines DL may be arranged more densely than the straight portions. Since the diagonal portions of the data lines DL are densely arranged, the non-display area NA may be reduced or minimized. For example, by narrowing the gap between the diagonal portions of the data lines DL, the length of the non-display area NA in the second direction DR2 may be reduced or minimized.

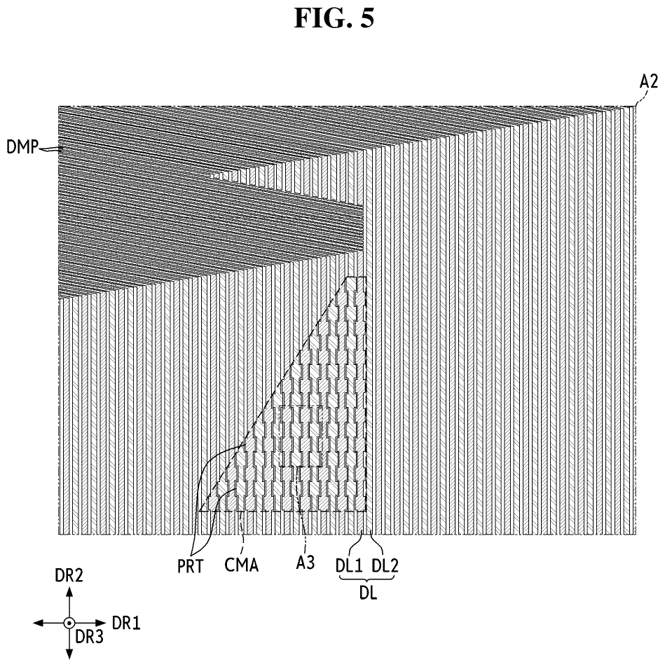

FIGS. 5 to 9 are plan views showing area A2 in FIG. 4 in detail. For example, FIGS. 5 to 9 show different embodiments of a part of the data lines DL located in area A2 of FIG. 4.

Referring to FIGS. 5 to 9 in addition to FIG. 4, the data lines DL may be distributed and disposed in the plurality of wiring areas DLA1, DLA2, and DLA3 spaced apart from each other with at least one isolation area SA interposed therebetween in a part of the non-display area NA. Accordingly, in a part of the non-display area NA, the data lines DL may not be continuously disposed along the first direction DR1 and the gap between adjacent data lines DL may be non-uniform. For example, the gap between the data lines DL spaced apart from each other with the isolation area SA interposed therebetween may be larger than the gap between the data lines DL disposed in each of the wiring areas DLA1, DLA2, and DLA3. For example, in the vicinity of the isolation area SA, the gap between the last first data line DL1 of the first wiring area DLA1 and the first second data line DL2 of the second wiring area DLA2 may be larger than the gap between adjacent first data lines DL1 in the first wiring area DLA1 and the gap between adjacent second data lines DL2 in the second wiring area DLA2.

In FIGS. 5 to 9, notations are given only to one first data line DL1 (e.g., the last first data line DL1 of the first wiring area DLA1) and one second data line DL2 (e.g., the first second data line DL2 of the second wiring area DLA2). However, as shown in FIG. 4, each of the data lines DL disposed in the first wiring area DLA1 may be the first data line DL1 and each of the data lines DL2 disposed in the second wiring area DLA2 may be the second data line DL2.

Since the data lines DL are not consecutively disposed in the non-display area NA, variation in resistance and/or capacitance between the data lines DL may occur. For example, the variation in resistance and capacitance of the data lines DL may occur between the wiring areas DLA1, DLA2, and DLA3.

In one embodiment, the resistance values of the data lines DL may become uniform by adjusting or changing the widths of the data lines DL. For example, the widths of the data lines DL may be differentiated to compensate for the variation in resistance values of the data lines DL (e.g., to reduce or offset variation in resistance values). For example, the resistance values of the data lines DL may become uniform by forming the relatively long data lines DL with a larger width and forming the relatively short data lines DL with a smaller width.

However, even if the resistance values of the data lines DL become uniform, the variation in capacitance between the data lines DL may occur due to the discontinuous arrangement of the data lines DL. For example, the variation in capacitance generated at the first data lines DL1 and capacitance generated at the second data lines DL2 at or around the boundary between the first wiring area DLA1 and the second wiring area DLA2 may be relatively large.

Accordingly, in embodiments, at the boundaries between the wiring areas DLA1, DLA2, and DLA3 where the variation in capacitance is large, the shape of the data lines DL may be changed or differentiated to reduce or offset the variation in capacitance between the data lines DL. In one embodiment, the shape of the data lines DL may be changed or differentiated at a portion where the arrangement gap between the data lines DL is relatively wide, for example, at a portion where the data lines DL extend in the second direction DR2. For example, the shape of some data lines DL may be changed or differentiated at straight portions (e.g., a part of the second non-display area NA2 where the wiring areas DLA1, DLA2, and DLA3 are sequentially arranged) of the data lines DL adjacent to the driving circuit 150. The straight portions of the data lines DL may be arranged at a wider gap than the diagonal portions of the data lines DL, so that a free space where the data lines DL may be partially expanded may exist between the data lines DL.

In one embodiment, in the first data lines DL1 and the second data lines DL2, the plurality of data lines DL adjacent to the boundary between the first wiring area DLA1 and the second wiring area DLA2 may include protruding patterns PRT protruding in a direction intersecting a longitudinal direction. Accordingly, the width of each of the plurality of data lines DL may be partially expanded at a portion where the protruding patterns PRT are disposed. Further, the gap between the plurality of data lines DL may be partially reduced at the portion where the protruding patterns PRT are disposed. Accordingly, the magnitude of the capacitance generated at the plurality of data lines DL may be increased.

The protruding patterns PRT may be formed at the plurality of data lines DL having a relatively small capacitance than neighboring other data lines DL. Accordingly, the variation in capacitance between the data lines DL may be reduced or minimized.

For example, the plurality of first data lines DL1 and/or the plurality of second data lines DL2 adjacent to the boundary between the first wiring area DLA1 and the second wiring area DLA2 may include the protruding patterns PRT protruding in the first direction DR1 corresponding to the width direction from the respective straight portions. Accordingly, the magnitude of the capacitance generated at the plurality of first data lines DL1 and/or the plurality of second data lines DL2 may increase and the capacitance generated at the data lines DL including the first data lines DL1 and the second data lines DL2 may become more uniform overall.

In the same manner, the variation in capacitance between the data lines DL may be reduced or minimized also at the boundary between the second wiring area DLA2 and the third wiring area DLA3 of FIG. 4. For example, the plurality of second data lines DL2 and/or the plurality of third data lines DL3 adjacent to the boundary between the second wiring area DLA2 and the third wiring area DLA3 may include the protruding patterns PRT protruding in the first direction DR1 corresponding to the width direction from the respective straight portions. Accordingly, the magnitude of the capacitance generated at the plurality of second data lines DL2 and/or the plurality of third data lines DL3 may increase and the capacitance generated at the data lines DL including the second data lines DL2 and the third data lines DL3 may become more uniform overall.

In one embodiment, the plurality of data lines DL may include different numbers of protruding patterns PRT. For example, when the compensation value of the capacitance required by the plurality of data lines DL are different or the capacitance of the plurality of data lines DL needs to be gradually changed, the amount of change in capacitance generated at the plurality of data lines DL may be adjusted or differentiated by differentiating the number or size of the protruding patterns PRT. For example, the plurality of data lines DL may include a larger number of protruding patterns PRT toward the boundaries (e.g., the boundary between the first wiring area DLA1 and the second wiring area DLA2, and/or the boundary between the second wiring area DLA2 and the third wiring area DLA3) between the wiring areas DLA1, DLA2, and DLA3. Accordingly, the rapid change in the capacitance generated at the data lines DL in each of the wiring areas DLA1, DLA2, and DLA3, and/or at the boundaries between the wiring areas DLA1, DLA2, and DLA3 may be prevented or mitigated, and the capacitance of the data lines DL may become uniform.

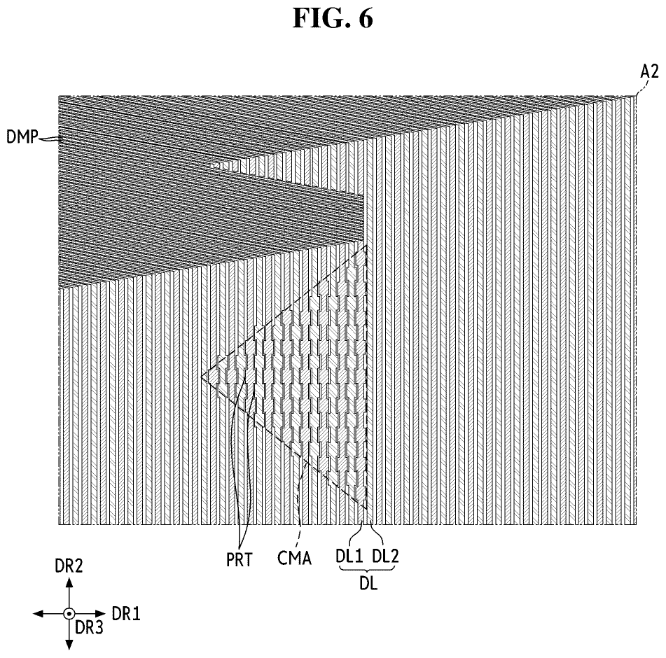

In one embodiment, the magnitude of the capacitance generated at the plurality of first data lines DL1 adjacent to the boundary between the first wiring area DLA1 and the second wiring area DLA2 may be smaller than the magnitude of the capacitance generated at the second data lines DL2 adjacent to the boundary between the first wiring area DLA1 and the second wiring area DLA2. In this case, as shown in FIGS. 5 and 6, in the vicinity of the boundary between the first wiring area DLA1 and the second wiring area DLA2, the magnitude of the capacitance generated at the first data lines DL1 may increase by setting a part of the first wiring area DLA1 as a capacitance matching area CMA, and forming the protruding patterns PRT (also referred to as “added patterns”, “auxiliary patterns” or “expanded patterns”) at a part of the first data lines DL1 located in the capacitance matching area CMA. When the capacitance matching area CMA does not include the second wiring area DLA2, the second data lines DL2 may not include the protruding patterns PRT.

In the embodiment of FIG. 5 or 6, the first data lines DL1 located in the capacitance matching area CMA may include the protruding patterns PRT of different numbers and/or sizes. For example, the number and/or size of the protruding patterns PRT formed at the first data lines DL1 located in the capacitance matching area CMA may gradually increase toward the second wiring area DLA2. Accordingly, the rapid change in the capacitance generated at the first data lines DL1 may be prevented or mitigated, and the capacitance of the first data lines DL1 may become uniform properly.

In the embodiment of FIG. 5 or 6, the length of the capacitance matching area CMA in the second direction DR2 may gradually increase toward the second wiring area DLA2. For example, the capacitance matching area CMA may have a trapezoidal shape or a triangular shape shown in FIG. 5 or 6, and the vertical length in the second direction DR2 may increase toward the second wiring area DLA2. Accordingly, the capacitance of the first data lines DL1 located in the capacitance matching area CMA may gradually change toward the second wiring area DLA2.

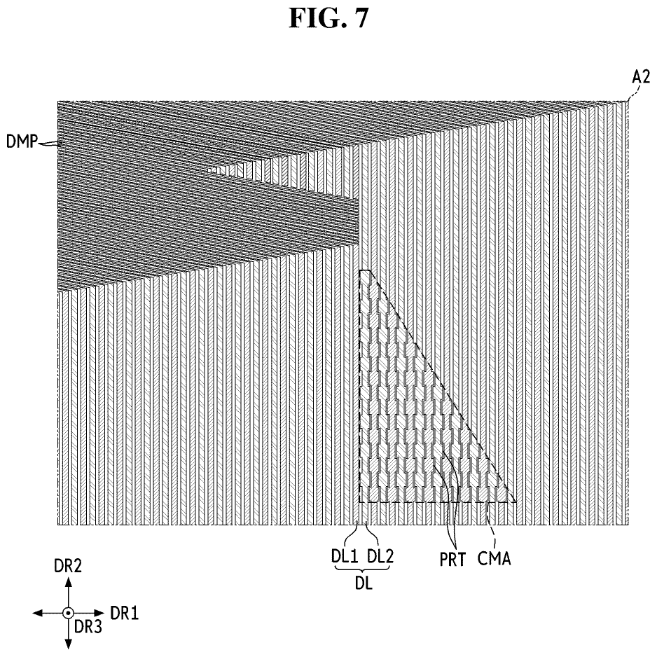

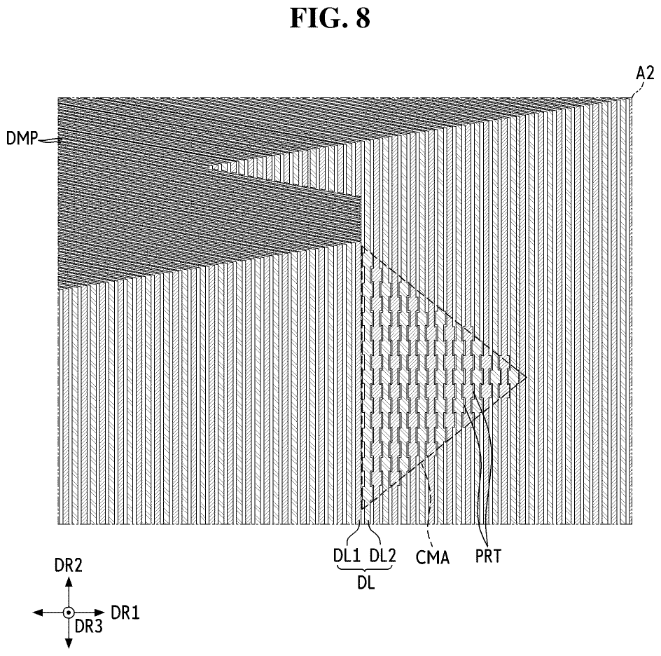

In another embodiment, the magnitude of the capacitance generated at the plurality of second data lines DL2 adjacent to the boundary between the first wiring area DLA1 and the second wiring area DLA2 may be smaller than the magnitude of the capacitance generated at the first data lines DL1 adjacent to the boundary between the first wiring area DLA1 and the second wiring area DLA2. In this case, as shown in FIGS. 7 and 8, in the vicinity of the boundary between the first wiring area DLA1 and the second wiring area DLA2, the magnitude of the capacitance generated at the second data lines DL2 may be increased by setting a part of the second wiring area DLA2 as the capacitance matching area CMA and forming the protruding patterns PRT at a part of the second data lines DL2 located in the capacitance matching area CMA. When the capacitance matching area CMA does not include the first wiring area DLA1, the first data lines DL1 may not include the protruding patterns PRT.

In the embodiment of FIG. 7 or 8, the second data lines DL2 located in the capacitance matching area CMA may include the protruding patterns PRT of different numbers and/or sizes. For example, the number and/or size of the protruding patterns PRT formed at the second data lines DL2 located in the capacitance matching area CMA may gradually increase toward the first wiring area DLA1. Accordingly, the rapid change in the capacitance generated at the second data lines DL2 may be prevented or mitigated, and the capacitance of the second data lines DL2 may become uniform properly.

In the embodiment of FIG. 7 or 8, the length of the capacitance matching area CMA in the second direction DR2 may gradually increase toward the first wiring area DLA1. For example, the capacitance matching area CMA may have a trapezoidal shape or a triangular shape shown in FIG. 7 or 8, and the vertical length in the second direction DR2 may increase toward the first wiring area DLA1. Accordingly, the capacitance of the second data lines DL2 located in the capacitance matching area CMA may gradually change toward the first wiring area DLA1.

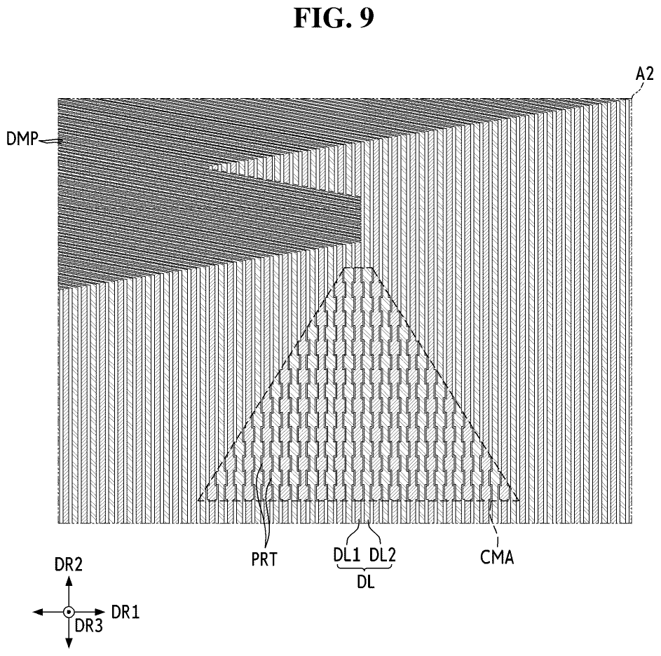

In another embodiment, the magnitude of the capacitance generated at the plurality of first data lines DL1 and the plurality of second data lines DL2 adjacent to the boundary between the first wiring area DLA1 and the second wiring area DLA2 may be smaller than the magnitude of the capacitance generated at other first data lines DL1 and/or other second data lines DL2. Further, the variation in capacitance may be increased toward the boundary between the first wiring area DLA1 and the second wiring area DLA2. In this case, as shown in FIG. 9, the magnitude of the capacitance generated at the plurality of first data lines DL1 and the plurality of second data lines DL2 may increase by setting a part of the first wiring area DLA1 and a part of the second wiring area DLA2 including the boundary between the first wiring area DLA1 and the second wiring area DLA2 as the capacitance matching area CMA, and forming the protruding patterns PRT at a part of the plurality of first data lines DL1 and a part of the plurality of second data lines DL2 located in the capacitance matching area CM.

In the embodiment of FIG. 9, the data lines DL located in the capacitance matching area CMA may include the protruding patterns PRT of different numbers and/or sizes. For example, the number and/or size of the protruding patterns PRT formed at the first data lines DL1 and the second data lines DL2 located in the capacitance matching area CMA may gradually increase toward the boundary between the first wiring area DLA1 and the second wiring area DLA2. Accordingly, the rapid change in the capacitance generated at the first data lines DL1 and the second data lines DL2 may be prevented or mitigated, and the capacitance of the first data lines DL1 and the second data lines DL2 may become uniform properly.

In the embodiment of FIG. 9, the capacitance matching area CMA may have a symmetrical shape with respect to the boundary between the first wiring area DLA1 and the second wiring area DLA2. For example, the capacitance matching area CMA may have a trapezoidal shape or a triangular shape that is symmetrical with respect to the boundary between the first wiring area DLA1 and the second wiring area DLA2. Accordingly, the protruding patterns PRT disposed in the capacitance matching area CMA may have a symmetrical shape with respect to the boundary between the first wiring area DLA1 and the second wiring area DLA2. Accordingly, the capacitances of the first data lines DL1 and the second data lines DL2 located in the capacitance matching area CMA may be gradually changed toward the boundary between the first wiring area DLA1 and the second wiring area DLA2.

In FIGS. 5 to 9, embodiments for compensating for the variation in capacitance between the data lines DL between the first wiring area DLA1 and the second wiring area DLA2 are disclosed using area A2 as an example, but the location of the capacitance matching area CMA is not limited thereto. For example, the variation in capacitance between the data lines DL at other boundaries, for example, between the second wiring area DLA2 and the third wiring area DLA3, may be compensated for in substantially the same or similar manner.

Further, the position or shape of the capacitance matching area CMA and/or the position, shape, number or size of the protruding patterns PRT for compensating for the variation in capacitance are not limited to the embodiments of FIGS. 5 to 9. For example, when it is necessary to adjust the capacitance of wires including the data lines DL, the position, shape, number, and/or size of the capacitance matching area CMA and/or the protruding patterns PRT may be variously changed depending on the location where it is desired to change the capacitance, or the amount or change or the direction of change in the capacitance.

In accordance with embodiments, the variation in capacitance of the data lines DL may be prevented, reduced, or minimized. Accordingly, the imbalance of the capacitance generated at the data lines DL may be adjusted or relieved, and the distortion of data signals may be prevented. Accordingly, the pixels PX may be stably driven, and the image quality of the display device 100 may be improved.

In one embodiment, dummy patterns DMP may be disposed in at least a part of the isolation area SA. For example, in the second non-display area NA2 or the like, the dummy patterns DMP may be disposed in the separation space between the first data lines DL1 and the second data lines DL2 (e.g., between the last first data line DL1 of the first wiring area DLA1 and the first second data line DL2 of the second wiring area DLA2). Similarly, in the second non-display area NA2 or the like, the dummy patterns DMP may be disposed in the separation space between the second data lines DL2 and the third data lines DL3 (e.g., between the last second data line DL2 of the second wiring area DLA2 and the first third data line DL3 of the third wiring area DLA3). In one embodiment, the dummy patterns DMP may be disposed in only one of the first non-display area NA1 and the second non-display area NA2, or may be disposed in both the first non-display area NA1 and the second non-display area NA2.

In one embodiment, the dummy patterns DMP may be disposed in the same conductive layer as the data lines DL. For example, in the second non-display area NA2 or the like, the dummy patterns DMP may be alternately disposed in the first conductive layer GCDL1 and the second conductive layer GCDL2. Since the dummy patterns DMP are disposed in the isolation area SA, the process variation caused by disposing the data lines DL at non-uniform intervals may be prevented or reduced. In one embodiment, the dummy patterns DMP may be floating or connected to the power line PL.

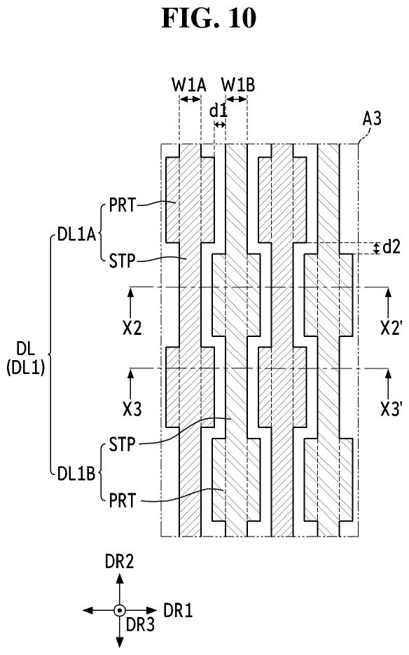

FIG. 10 is a plan view showing area A3 of FIG. 5 in detail. For example, FIG. 10 shows in detail one embodiment of the protruding patterns PRT formed at the data lines DL (e.g., the first data lines DL1) located in area A3 of FIG. 5.

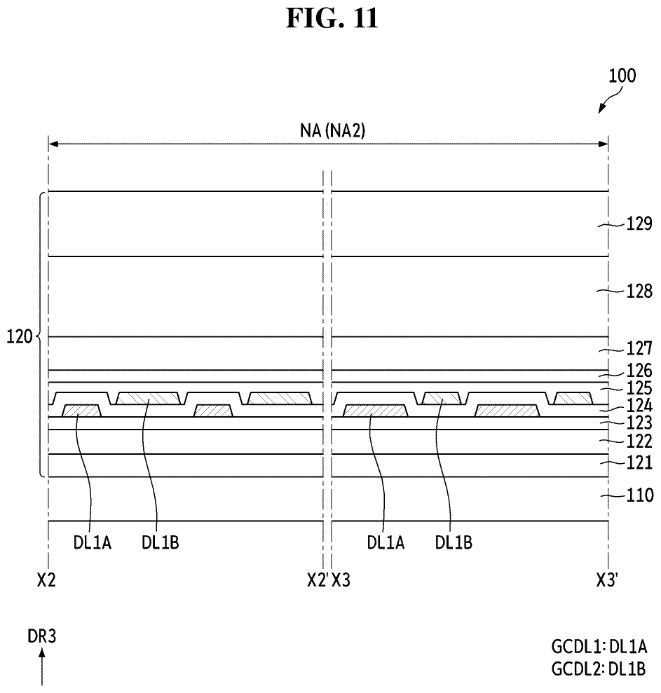

FIG. 11 is a cross-sectional view showing a display device according to one embodiment. For example, FIG. 11 shows one embodiment of the cross section of the display device 100 in a part of the non-display area NA (e.g., the second non-display area NA2) corresponding to lines X2-X2′ and X3-X3′ of FIG. 10.

Referring to FIGS. 10 and 11 in addition to FIGS. 4 to 9, the protruding patterns PRT may be disposed in a part of each of the data lines DL located in the capacitance matching area CMA. For example, the protruding patterns PRT may be disposed in a part of each of the first data lines DL1 located in the capacitance matching area CMA.

In one embodiment, the protruding patterns PRT may be alternately disposed at the data lines DL. Accordingly, the protruding patterns PRT may be formed while efficiently utilizing the space between the data lines DL and the variation in capacitance of the data lines DL may be properly compensated for by the protruding patterns PRT.

The data lines DL located in the capacitance matching area CMA may have first widths W1A and W1B at the respective straight portions STP. In one embodiment, the first widths W1A and W1B of the data lines DL disposed in each of the wiring areas DLA1, DLA2, and DLA3 may be substantially the same or similar to each other. Alternatively, the first widths W1A and W1B of the data lines DL disposed in each of the wiring areas DLA1, DLA2, and DLA3 may be different. For example, the first widths W1A and W1B of the data lines DL may be finely adjusted or differentiated to compensate for variation in resistance of the data lines DL disposed in each of the wiring areas DLA1, DLA2, and DLA3.

In embodiments, the data lines DL located in the capacitance matching area CMA may have a width wider than the first widths W1A and W1B at the portions where the respective protruding patterns PRT are disposed. The distance (e.g., a first gap d1 in the first direction DR1 and/or a second gap d2 in the second direction DR2) between the data lines DL in the capacitance matching area CMA may be reduced due to the protruding patterns PRT. Accordingly, the capacitance generated at the data lines DL located in the capacitance matching area CMA may be increased.

In one embodiment, the magnitude of the capacitance generated at the data lines DL may be properly or easily adjusted by adjusting the number or gap of the protruding patterns PRT. For example, the magnitude of the capacitance generated at the data lines DL may be finely adjusted by adjusting at least one of the arrangement shape of the protruding patterns PRT formed at the data lines DL, the number of the protruding patterns PRT, the size of the protruding patterns PRT, or the interval (e.g., the first gap d1 and/or the second gap d2) at which the protruding patterns PRT are disposed.

Even if the protruding patterns PRT are formed only at the data lines DL located in the capacitance matching area CMA, the protruding patterns PRT are disposed only at a part of each of the data lines DL, so that the resistance values of the data lines DL may be maintained uniformly overall. For example, the protruding patterns PRT may be disposed only at a part of the data lines DL located in the capacitance matching area CMA except both ends thereof, and the overall width of each of the data lines DL may be maintained uniformly. Accordingly, the variation in capacitance between the data lines DL may be compensated for by changing (e.g., increasing) the capacitance generated at the data lines DL without substantially changing the resistance value of each of the data lines DL located in the capacitance matching area CMA.

In one embodiment, the data lines DL may be alternately arranged in at least two conductive layers (e.g., the first conductive layer GCDL1 and the second conductive layer GCDL2) disposed on the substrate 110. For example, the data lines DL may include data lines DL1A disposed in the first conductive layer GCDL1 on the substrate 110, and data lines DL1B disposed in the second conductive layer GCDL2 on the second insulating layer 124 covering the first conductive layer GCDL1 in at least a part of the non-display area NA (e.g., the second non-display area NA2). Further, the data lines DL1A in the first conductive layer GCDL1 and the data lines DL1B in the second conductive layer GCDL2 may be alternately disposed along the first direction DR1.

However, the embodiments are not limited thereto. For example, the data lines DL may be disposed in the same conductive layer or may be distributed and arranged in a plurality of conductive layers including at least one conductive layer other than the first conductive layer GCDL1 and the second conductive layer GCDL2. In addition, the positions of the data lines DL may be variously changed depending on embodiments.

As described above, the data lines DL may not be consecutively disposed in at least a part of the non-display area NA. For example, the data lines DL may be distributed and disposed in the wiring areas DLA1, DLA2, and DLA3 spaced apart from each other with the isolation area SA, where the power line PL and the like are disposed, interposed therebetween in at least a part of the non-display area NA. The discontinuous arrangement of the data lines DL may cause variation in capacitance of the data lines DL.

However, in accordance with the above-described embodiments, the protruding patterns PRT may be formed in at least some of the data lines DL to reduce or compensate for the variation in capacitance of the data lines DL. For example, the protruding patterns PRT may be formed in at least some of the data lines DL to reduce or compensate for the variation in capacitance of the data lines DL between the wiring areas DLA1, DLA2, and DLA3. Accordingly, the variation in capacitance of the data lines DL may be reduced or minimized, and data signals may be stably transmitted to the pixels PX.

In concluding the detailed description, those skilled in the art will appreciate that many variations and modifications can be made to the embodiments without substantially departing from the principles of the present inventive concept. Therefore, the disclosed embodiments of the inventive concept are used in a generic and descriptive sense only and not for purposes of limitation.

What is claimed is:

1. A display device comprising:
a substrate comprising a display area and a non-display area;
pixels disposed in the display area on the substrate; and
data lines comprising first data lines and second data lines disposed in the display area and the non-display area on the substrate,
wherein the non-display area comprises a first wiring area in which the first data lines are disposed and a second wiring area in which the second data lines are disposed, and
wherein at least one data line disposed adjacent to a boundary between the first wiring area and the second wiring area comprises protruding patterns which protrude in a first direction intersecting a longitudinal direction of the data lines.

2. The display device of claim 1, wherein the first direction is a width direction of the data lines, and
wherein a width of the at least one data line is partially expanded at portions where the protruding patterns are disposed.

3. The display device of claim 1, wherein a plurality of data lines disposed adjacent to the boundary comprise the protruding patterns, and
wherein a gap between adjacent data lines of the plurality of data lines is partially reduced at the portions where the protruding patterns are disposed.

4. The display device of claim 1, further comprising a driving circuit disposed in the non-display area on the substrate,
wherein the data lines are connected between the driving circuit and the pixels.

5. The display device of claim 4, wherein the non-display area comprises a first non-display area, a bending area, and a second non-display area sequentially disposed along a second direction intersecting the first direction between the display area and the driving circuit.

6. The display device of claim 5, wherein the first wiring area and the second wiring area are sequentially disposed along the first direction in the first non-display area, the bending area, and the second non-display area.

7. The display device of claim 6, further comprising an isolation area which is disposed between the first wiring area and the second wiring area in the non-display area, wherein the data lines are not disposed in the isolation area.

8. The display device of claim 7, wherein the first data lines are consecutively disposed along the first direction in the first wiring area,
wherein the second data lines are consecutively disposed along the first direction in the second wiring area, and
wherein the isolation area is disposed between the first data lines and the second data lines in the non-display area.

9. The display device of claim 7, further comprising a power line disposed in the display area and the non-display area on the substrate,
wherein the power line is disposed in the isolation area in the non-display area.

10. The display device of claim 5, wherein the data lines comprise straight portions extending in the second direction and diagonal portions extending in a diagonal direction intersecting the first and second directions and arranged more densely than the straight portions.

11. The display device of claim 10, wherein a plurality of data lines disposed adjacent to the boundary comprise the protruding patterns, and
wherein the protruding patterns protrude in the first direction from the respective straight portions of the plurality of data lines.

12. The display device of claim 5, wherein the first wiring area and the second wiring area are sequentially disposed along the first direction in the second non-display area, and
wherein data lines disposed close to the boundary include the protruding patterns.

13. The display device of claim 1, wherein at least two data lines disposed adjacent to each other comprise different numbers of protruding patterns.

14. The display device of claim 13, wherein a data line disposed closer to the boundary comprises a greater number of protruding patterns than that disposed far from the boundary.

15. The display device of claim 1, wherein first data lines disposed close to the boundary comprise the protruding patterns and second data lines disposed close to the boundary do not comprise the protruding patterns.

16. The display device of claim 1, wherein second data lines disposed close to the boundary between the first wiring area and the second wiring area comprise the protruding patterns and first data lines disposed close to the boundary between the first wiring area and the second wiring area do not comprise the protruding patterns.

17. The display device of claim 1, wherein first data lines and second data lines disposed close to the boundary between the first wiring area and the second wiring area comprise the protruding patterns.

18. The display device of claim 17, wherein protruding patterns disposed in the first wiring area and the second wiring area are disposed symmetrically with respect to the boundary between the first wiring area and the second wiring area.

19. The display device of claim 1, wherein protruding patterns disposed adjacent to each other have an interlocked shape.

20. The display device of claim 1, wherein the data lines are alternately disposed in a first conductive layer on the substrate and a second conductive layer on an insulating layer covering the first conductive layer in the non-display area.

21. An electronic device for providing an image, comprising:
a display device comprising:
a substrate comprising a display area and a non-display area;
pixels disposed in the display area on the substrate; and
data lines comprising first data lines and second data lines disposed in the display area and the non-display area on the substrate,
wherein the non-display area comprises a first wiring area in which the first data lines are disposed and a second wiring area in which the second data lines are disposed, and
wherein at least one data line disposed adjacent to a boundary between the first wiring area and the second wiring area comprises protruding patterns which protrude in a first direction intersecting a longitudinal direction of the data lines.
